(19) United States
(12) Patent Application Publication
(10) Pub. No.: US 2024/0220686 A1
(43) Pub. Date: Jul. 4, 2024

(54) URBAN-REGION ROAD NETWORK VEHICLE-PASSAGE FLOW PREDICTION METHOD AND SYSTEM BASED ON HYBRID DEEP LEARNING MODEL

(71) Applicant: NANJING NORMAL UNIVERSITY, Jiangsu (CN)

(72) Inventors: Hong ZHANG, Jiangsu (CN); Xin XU, Jiangsu (CN); Fei GUO, Jiangsu (CN); Huandong WANG, Jiangsu (CN)

(73) Assignee: NANJING NORMAL UNIVERSITY, Jiangsu (CN)

(21) Appl. No.: 18/558,734

(22) PCT Filed: May 16, 2022
(86) PCT No.: PCT/CN2022/093053

§ 371 Date: Nov. 2, 2023

(30) Foreign Application Priority Data
May 28, 2021 (CN) 202110588265.8

(51) Int. Cl. G06F 30/27

(52) U.S. Cl. CPC G06F 30/27

(57) ABSTRACT

Disclosed are urban-region road network vehicle-passage flow prediction method and system based on a hybrid deep learning model. The method comprises: compiling statistics on traffic flow on the basis of vehicle-passage data of a checkpoint; performing spatial and temporal distribution feature analysis on vehicle-passage flow data of the checkpoint, and performing feature extraction according to an analysis result, so as to acquire a spatial and temporal influence factor; constructing and training a ConvLSTM and BILSTM hybrid deep learning model according to the spatial and temporal influence factor; performing synchronous prediction on traffic flow of an urban-region road network, selecting prediction loss functions and evaluation indicators, and performing visual representation on a result; and calculating a traffic flow variation degree by means of a linear time series prediction model Prophet, and performing traffic state identification, so as to realize traffic state pre-determination.

### TECHNICAL FIELD

The present invention belongs to the technical field of model calculation, and particularly relates to an urban-region road network vehicle-passage flow prediction method and system based on a ConvLSTM and BILSTM hybrid deep learning model.

### BACKGROUND

In medium- and large-sized cities, a growth rate of the number of vehicles is much higher than the construction progress of transportation facilities, so the construction of urban transportation infrastructure cannot meet the increasing traffic demand, resulting in an imbalance between supply and demand of urban transportation, and the contradiction has become increasingly acute, causing such social problems as economic losses, casualties, and deterioration of ecological environment. Traffic congestion has become one of the important reasons hindering urban development. An important means to cope with urban traffic congestion is to accurately determine the traffic operation status based on real-time traffic information on the road network, and take scientific and reasonable traffic control measures to guide the traffic. Therefore, it is necessary to realize real-time and accurate traffic flow prediction, identify the traffic operation status of road network and predict road traffic operation status in advance, providing effective data support for real-time traffic control. The field of intelligent transportation research has become a hotspot.

With the rapid development of traffic electronic equipment, there are increasingly abundant road traffic survey methods, the accuracy of indicators is improved, and the indicator system is expanded. Traffic electronic equipment capable of collecting comprehensive information from large samples is widely used. A road high-definition camera checkpoint monitoring system is one of such traffic electronic equipment. Vehicle-passage flow data of the checkpoint can accurately identify the information of each vehicle passing through the checkpoint, and can accurately calculate traffic flow. It has the advantages of easy maintenance and strong applicability, has become an important data source for urban intelligent transportation and has been widely used in traffic state identification, playing an important role in traffic flow prediction. The existing main methods for traffic flow prediction and traffic state recognition on the basis of vehicle-passage flow data of the checkpoint have the shortcomings of insufficient data feature analysis and only applicable to a single road condition scenario.

Therefore, a new technical solution is needed to solve these problems.

### SUMMARY

An objective of the present invention: in order to overcome the problems of insufficient data feature analysis and only applicable to a single road condition scenario, the present invention provides an urban-region road network vehicle-passage flow prediction method and system based on a ConvLSTM and BILSTM hybrid deep learning model, so as to realize the prediction of traffic congestion.

Technical solution: in order to achieve the above objective, the present invention provides an urban-region road network vehicle-passage flow prediction method and system based on a hybrid deep learning model, including the following steps:
S1: making statistics on traffic flow on the basis of vehicle-passage data of a checkpoint, and calculating real-time vehicle-passage flow and cumulative vehicle-passage flow;
S2: performing spatial and temporal distribution feature analysis on vehicle-passage flow data of the checkpoint based on the flow data obtained in the step S1, and performing feature extraction according to an analysis result to acquire a spatial and temporal influence factor;
S3: constructing and training a ConvLSTM and BiLSTM hybrid deep learning model according to the spatial and temporal influence factor;
S4: performing synchronous prediction on traffic flow of an urban-region road network through the constructed ConvLSTM and BiLSTM hybrid deep learning model, selecting prediction loss functions and evaluation indicators, and performing visual representation on a result; and
S5: calculating a traffic flow variation degree by means of a linear time series prediction model Prophet, performing traffic state identification, and realizing traffic state pre-determination according to the predication results obtained in the step S4.

Further, the step S1 specifically includes: making statistics of vehicle-passage flow data of a checkpoint of each intersection during each period of time on different time scales, and calculating real-time vehicle-passage flow and cumulative vehicle-passage flow by using the traffic flow statistics module;

Further, the step S1 specifically includes:
A1: making statistics of vehicle-passage flow data of each checkpoint of each intersection during each period of time on different time scales; and
A2: taking the daily set time as the starting time for statistics, and calculating the daily cumulative traffic flow at each intersection.

Further, the spatial and temporal distribution feature analysis in the step S2 includes the temporal distribution periodic feature analysis, temporal distribution trend feature analysis, temporal distribution continuous feature analysis and spatial distribution correlation feature analysis.

Further, in the spatial and temporal distribution feature analysis in the step S2, the power spectral method is adopted to analyze the temporal distribution periodic feature of vehicle-passage flow data of the checkpoint; the DBEST model is adopted to analyze the temporal distribution trend feature of vehicle-passage flow data of the checkpoint; a time headway is calculated to analyze the temporal distribution continuous feature of vehicle-passage flow data of the checkpoint; and the correlation matrix method is adopted to analyze the spatial distribution correlation feature of vehicle-passage flow data of the checkpoint.

Further, the method for “constructing and training a ConvLSTM and BiLSTM hybrid deep learning model” in the step S3 includes the following steps:
B1: organizing model data, mapping the traffic flow data of a prediction point and traffic flow data points in the vicinity of the prediction point to a one-dimensional data vector, and forming a two-dimensional matrix of one-dimensional vectors at various moments to represent traffic flow data of the predicted checkpoint and its upstream checkpoint during a short period of time;
B2: using the ConvLSTM structure to extract spatial and temporal feature of real-time traffic flow data; using the BiLSTM to extract periodic feature of traffic flow, splicing the two parts of extracted feature data together through a feature fusion layer, and finally performing feature regression through a fully connected network to complete the model construction; and
B3: inputting the real-time checkpoint traffic flow data, checkpoint spatial correlation matrix, and checkpoint historical period traffic flow data into the model for training, and calculating a training result model.

Further, the prediction loss functions in the step S4 of the present embodiment are specifically:

$$MAE = \frac{1}{n} {\sum }_{t = 1}^{n} \vert {F}_{p} - {F}_{t} \vert \\ RMSE = \sqrt[2]{\frac{1}{n} {\sum }_{t = 1}^{n} {( {F}_{p} - {F}_{t} )}^{2}} \\ MAPE = \frac{100}{n} {\sum }_{t = 1}^{n} \vert \frac{{F}_{p} - {F}_{t}}{{F}_{t}} \vert \\ Loss = \frac{1}{n} ( {\sum }_{t = 1}^{n} {( {F}_{p} - {F}_{t} )}^{2} + φ {\sum }_{i = 1 n}^{} \vert {W}_{i} \vert + φ {\sum }_{i = 1}^{n} \sqrt{{W}_{i}^{2}} )$$

where Fₚ is a deep neural network predicted value of the vehicle-passage flow. Fₜ is an actual value of the vehicle-passage flow, and φ and Wᵢ are parameters of the model;

Evaluation indicators include absolute mean error, root mean square error and mean absolute error percentage.

Further, the step S5 specifically includes:
C1: calculating a traffic flow variation degree. The traffic flow variation degree is a parameter that reflects the degree of variation in the traffic state at the checkpoint intersection, and the traffic state can be considered to be several continuous states between complete congestion and complete smoothness. When the traffic state does not change significantly, the traffic flow variation degree will not change greatly, and the model prediction value will be more accurate; when the traffic state changes sharply, the model prediction value will deviate greatly from the real traffic flow; and the calculation formula is as follows:

$$P ( f \vert μ , {σ}^{2} ) = \frac{1}{σ \sqrt{2 π}} exp ( - \frac{{( x - μ )}^{2}}{2 {σ}^{2}} ) \\ {v}_{j} = s \cdot {v}_{j - 1} + ( 1 - s ) {( {f}_{j} - {\hat{f}}_{i , j} )}^{2}$$

where the expected value μ and the variance σ² are two important parameters of normal distribution, the target value f is the truth value of the current traffic flow, vⱼ represents the variance at the j moment. s is the weight value of the preset variance from the previous moment that is continuously retained until the current moment, and fⱼ represents the real traffic flow at the j moment; and
C2: setting a threshold for the traffic flow variation degree. When the traffic flow variation degree of a road section in a smooth state is greater than the threshold, it means that the traffic state of the road section has changed to a congestion-forming state; when the traffic flow variation degree of the road section in a congestion-forming state is lower than the threshold, it means that the traffic state of the road section has changed to a congested state; when the traffic flow variation degree of the road section in a congested state is greater than the threshold, it means that the traffic state of the road section has changed to a congestion-relief state; and when the traffic flow variation degree of the road section in a congestion-relief is lower than the threshold, it means that the traffic state of the road section has changed to a smooth state; such that the traffic state identified and the traffic state is pre-determined.

The present invention further provides an urban-region road network vehicle-passage flow prediction system based on a ConvLSTM and BILSTM hybrid deep learning model, including a traffic flow statistics module, a checkpoint vehicle-passage flow data spatial-temporal distribution feature analysis module, a training module of an urban-region road network vehicle-passage flow prediction model, a prediction module of an urban-region road network vehicle-passage flow prediction model, and an urban-region road network traffic state pre-determination module; where the traffic flow statistics module is used for making statistics of vehicle-passage flow data of a checkpoint of each intersection during each period of time and calculating real-time vehicle-passage flow and cumulative vehicle-passage flow; the checkpoint vehicle-passage flow data spatial-temporal distribution feature analysis module is used for making visual analysis of temporal distribution periodic feature, trend feature, continuous feature and spatial distribution correlation feature of vehicle-passage flow data at the checkpoint; the training module of an urban-region road network vehicle-passage flow prediction model is used for constructing a ConvLSTM and BiLSTM hybrid deep learning model and training input data to form a stable and highly-fitting urban-region road network vehicle-passage flow prediction model; the prediction module of an urban-region road network vehicle-passage flow prediction model is used for inputting historical data related to the urban-region road network vehicle-passage flow that needs to be predicted, and bringing them into the model for prediction; and the urban-region road network traffic state pre-determination module is used for calculating a traffic flow variation degree, and identifying traffic state, so as to realize traffic state pre-determination.

Beneficial effects: compared with the prior art, the present invention explores the temporal and spatial correlation feature of different traffic checkpoints by analyzing the temporal and spatial feature of vehicle-passage data of the checkpoint, constructs a checkpoint traffic flow prediction model based on various checkpoints in a city, researches on the traffic state identification method, and converts the predicted traffic flow data into traffic state, thereby realizing the prediction of traffic congestion and overcoming the problems of insufficient data feature analysis and only applicable to a single road condition scenario, such that traffic management departments can be helped to perform dynamic management and scheduling on urban roads, perform optimal management on urban road networks on a global scale, and formulate management policies and management schemes, thereby providing effective data support for traffic managers and decision makers.

### BRIEF DESCRIPTION OF THE DRAWINGS

FIG. 1 is a schematic diagram of a ConvLSTM network structure;

FIG. 2 is a schematic diagram of a BiLSTM network structure;

FIG. 3 is a schematic diagram of a basic network structure of a hybrid deep learning traffic flow prediction model; and

FIG. 4 is a schematic flowchart of a method of the present invention.

### DETAILED DESCRIPTIONS OF THE EMBODIMENTS

The present invention will be further described below in conjunction with accompanying drawings and specific embodiments. It should be understood that these embodiments are only intended to illustrate the present invention but not to limit the scope of the present invention. Various modifications in equivalent forms made by those skilled in the art after reading through the present invention should fall within the scope defined by the appended claims of the present invention.

The present invention provides an urban-region road network vehicle-passage flow prediction system based on a ConvLSTM and BiLSTM hybrid deep learning model, including a traffic flow statistics module, a checkpoint vehicle-passage flow data spatial-temporal distribution feature analysis module, a training module of an urban-region road network vehicle-passage flow prediction model, a prediction module of an urban-region road network vehicle-passage flow prediction model, and an urban-region road network traffic state pre-determination module; where the traffic flow statistics module is used for making statistics of vehicle-passage flow data of a checkpoint of each intersection during each period of time and calculating real-time vehicle-passage flow and cumulative vehicle-passage flow; the checkpoint vehicle-passage flow data spatial-temporal distribution feature analysis module is used for making visual analysis of temporal distribution periodic feature, trend feature, continuous feature and spatial distribution correlation feature of vehicle-passage flow data at the checkpoint; the training module of an urban-region road network vehicle-passage flow prediction model is used for constructing a ConvLSTM and BiLSTM hybrid deep learning model and training input data to form a stable and highly-fitting urban-region road network vehicle-passage flow prediction model; the prediction module of an urban-region road network vehicle-passage flow prediction model is used for inputting historical data related to the urban-region road network vehicle-passage flow that needs to be predicted, and bringing them into the model for prediction; and the urban-region road network traffic state pre-determination module is used for calculating a traffic flow variation degree, and identifying traffic state, so as to realize traffic state pre-determination.

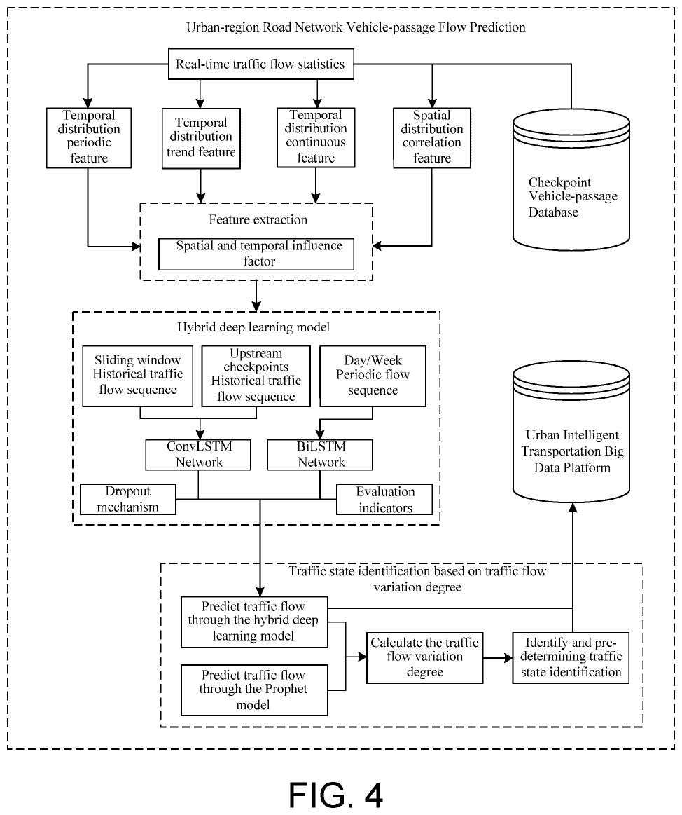

Based on the above prediction system, the present invention provides an urban-region road network vehicle-passage flow prediction method based on a hybrid deep learning model, as shown in FIG. 4, including the following steps:
S1: making statistics of vehicle-passage flow data of a checkpoint of each intersection during each period of time on different time scales, and calculating real-time vehicle-passage flow and cumulative vehicle-passage flow by using the traffic flow statistics module;
S2: performing spatial and temporal distribution feature analysis on vehicle-passage flow data of the checkpoint based on the flow data obtained in the step S1, and performing feature extraction according to an analysis result to acquire a spatial and temporal influence factor by using the checkpoint vehicle-passage flow data spatial-temporal distribution feature analysis module;
S3: constructing and training a ConvLSTM and BiLSTM hybrid deep learning model according to the spatial and temporal influence factor by using the training module of an urban-region road network vehicle-passage flow prediction model;
S4: performing synchronous prediction on traffic flow of an urban-region road network through the constructed ConvLSTM and BILSTM hybrid deep learning model, selecting prediction loss functions and evaluation indicators, and performing visual representation on a result by using the prediction module of an urban-region road network vehicle-passage flow prediction model; and
S5: calculating a traffic flow variation degree by means of a linear time series prediction model Prophet, performing traffic state identification, and realizing traffic state pre-determination according to the predication results obtained in the step S4 by using the urban-region road network traffic state pre-determination module, thereby providing business application methods for high-precision traffic flow prediction.

In the present embodiment, the step S1 specifically includes the following steps:
A1: making statistics of vehicle-passage flow data of each checkpoint of each intersection during each period of time on different time scales, with the calculation formula as follows:

$$\hat{μ} = N * P / T$$

A2: taking 3:00 every day as the starting time for statistics, and calculating the daily cumulative traffic flow at each intersection.

The spatial and temporal distribution feature analysis in the step S2 of the present embodiment includes the temporal distribution periodic feature analysis, temporal distribution trend feature analysis, temporal distribution continuous feature analysis and spatial distribution correlation feature analysis.

In the spatial and temporal distribution feature analysis, the power spectral method is adopted to analyze the temporal distribution periodic feature of vehicle-passage flow data of the checkpoint, with the calculation formula as follows:

$$C ( k ) = \frac{1}{n - k} {\sum }_{i = 1}^{n - k} ( \frac{T ( i ) - \overline{T}}{s} ) ( \frac{T ( i + k ) - \overline{T}}{s} ) \\ {S}_{c} = \frac{1}{m} [ C ( 0 ) + 2 {\sum }_{k = 1}^{m - 1} C ( k ) cos \frac{c π k}{m} + r ( m ) cos c π ] \\ {H}_{C} = 2 m / c$$

The DBEST model is adopted to analyze the temporal distribution trend feature of vehicle-passage flow data of the checkpoint, with the calculation formula as follows:

$${f}_{( i )} = \{ \begin{matrix}1 , if sign ( Δ {V}_{( i - 1 , i )} = - sign ( Δ {V}_{( i , i + 1 )} ) \\ 0 , otherwise\end{matrix} \\ Δ {V}_{( i - 1 , i )} = {V}_{( i )} - {V}_{( i - 1 )} \\ Δ {V}_{( i , i + 1 )} = {V}_{( i + 1 )} - {V}_{( i )} \\ {k}_{( i )} = \{ \begin{matrix}1 , if sign ( Δ {V}_{( i - 1 , i )} ) = - sign ( Δ {V}_{( i , i + 1 )} ) \\ 1 , if {f}_{( i )} = 0 and {d}_{( i )} > ε \\ 0 , if {f}_{( i )} = 0 and {d}_{( i )} < ε\end{matrix}$$

A time headway is calculated to analyze the temporal distribution continuous feature of vehicle-passage flow data of the checkpoint, where the time headway is the time interval between front ends of two consecutive vehicles passing through a certain section in a queue of vehicles traveling on the same lane. In the present embodiment, the time headway refers to the time interval between two vehicle passing events in each lane recorded at the checkpoint, with the calculation formula as follows:

$$Δ {t}_{i} = {t}_{i} - {t}_{i - 1}$$

The correlation matrix method is adopted to analyze the spatial distribution correlation feature of vehicle-passage flow data of the checkpoint.

In the step S3 of the present embodiment, relevant influence factor is selected in combination with the spatial and temporal distribution feature in the step S2, and a spearman coefficient between the vehicle-passage flow data of the checkpoint and the spatial and temporal influence factor is then calculated, with the calculation formula as follows:

$$ρ = 1 - \frac{6 Σ {d}_{i}^{2}}{n ( {n}^{2} - 1 )}$$

In the step S3 of the present embodiment, the method for “constructing and training a ConvLSTM and BILSTM hybrid deep learning model” includes the following steps:
B1: organizing model data, mapping the traffic flow data of a prediction point and traffic flow data points in the vicinity of the prediction point to a one-dimensional data vector, and forming a two-dimensional matrix of one-dimensional vectors at various moments to represent traffic flow data of the predicted checkpoint and its upstream checkpoint during a short period of time, with the calculation formula as follows:

$$F = [ \begin{matrix}{F}_{1}^{p} & {F}_{1}^{n} \\ ⋮ & ⋮ \\ {F}_{t}^{p} & {F}_{t}^{n}\end{matrix} ]$$

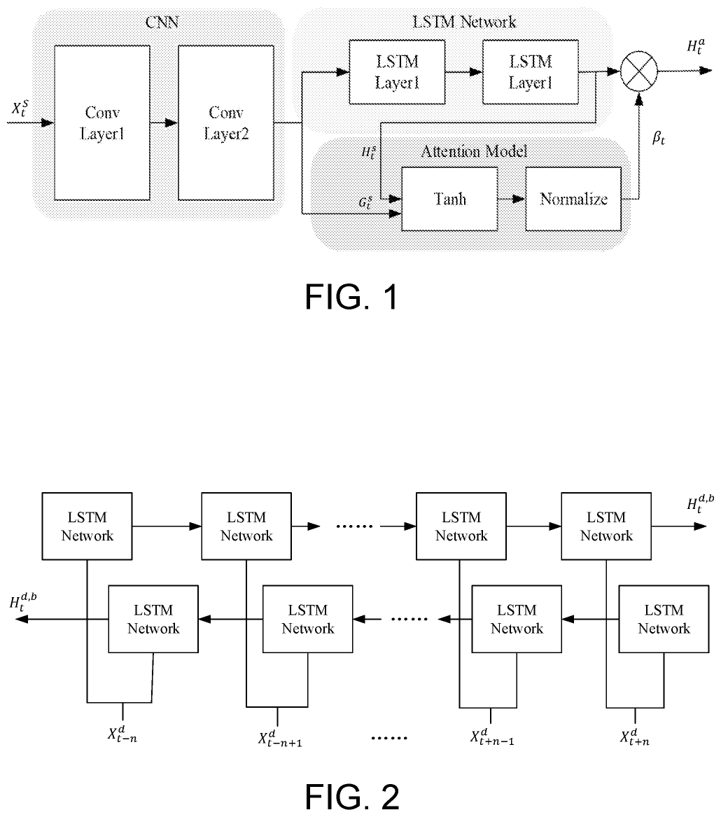

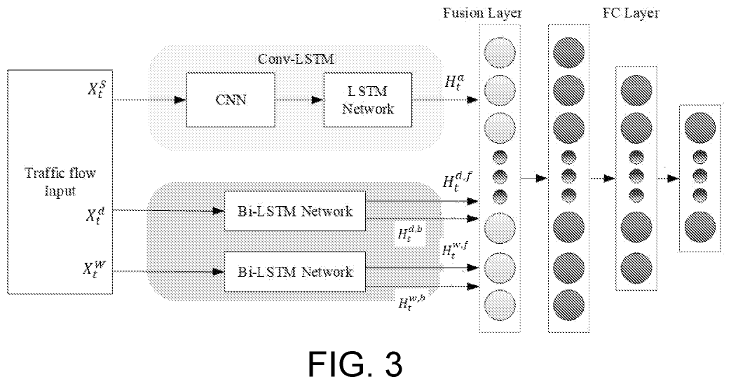

B2: designing a ConvLSTM structure as shown in FIG. 1, using the ConvLSTM structure to extract spatial and temporal feature of real-time traffic flow data; designing a BiLSTM structure as shown in FIG. 2, using the BILSTM to extract periodic feature of traffic flow, splicing the two parts of extracted feature data together through a feature fusion layer, and finally performing feature regression through a fully connected network to complete the model construction. Basic network structure of the model is shown in FIG. 3; and
B3: inputting the real-time checkpoint traffic flow data, checkpoint spatial correlation matrix, and checkpoint historical period traffic flow data into the model for training, and calculating a training result model.

The prediction loss functions in the step S4 of the present embodiment are specifically:

$$MAE = \frac{1}{n} {\sum }_{t = 1}^{n} \vert {F}_{p} - {F}_{t} \vert \\ RMSE = \sqrt[2]{\frac{1}{n} {\sum }_{t = 1}^{n} {( {F}_{p} - {F}_{t} )}^{2}} \\ MAPE = \frac{100}{n} {\sum }_{t = 1}^{n} \vert \frac{{F}_{p} - {F}_{t}}{{F}_{t}} \vert \\ Loss = \frac{1}{n} ( {\sum }_{t = 1}^{n} {( {F}_{p} - {F}_{t} )}^{2} + φ {\sum }_{i = 1 n}^{} \vert {W}_{i} \vert + φ {\sum }_{i = 1}^{n} \sqrt{{W}_{i}^{2}} )$$

where Fₚ is a deep neural network predicted value of the vehicle-passage flow, Fₜ is an actual value of the vehicle-passage flow, and φ and Wᵢ are parameters of the model;
Evaluation indicators include absolute mean error, root mean square error and mean absolute error percentage.

In the present embodiment, the step S5 specifically includes the following steps:
C1: calculating a traffic flow variation degree. The traffic flow variation degree is a parameter that reflects the degree of variation in the traffic state at the checkpoint intersection, and the traffic state can be considered to be several continuous states between complete congestion and complete smoothness. When the traffic state does not change significantly, the traffic flow variation degree will not change greatly, and the model prediction value will be more accurate; when the traffic state changes sharply, the model prediction value will deviate greatly from the real traffic flow; and the calculation formula is as follows:

$$P ( f \vert μ , {σ}^{2} ) = \frac{1}{σ \sqrt{2 π}} exp ( - \frac{{( x - μ )}^{2}}{2 {σ}^{2}} ) \\ {v}_{j} = s \cdot {v}_{j - 1} + ( 1 - s ) {( {f}_{j} - {\hat{f}}_{i , j} )}^{2}$$

where the expected value μ and the variance σ² are two important parameters of normal distribution, the target value f is the truth value of the current traffic flow, vⱼ represents the variance at the j moment. s is the weight value of the preset variance from the previous moment that is continuously retained until the current moment, and fⱼ represents the real traffic flow at the j moment;
C2: setting a threshold for the traffic flow variation degree. When the traffic flow variation degree of a road section in a smooth state is greater than the threshold, it means that the traffic state of the road section has changed to a congestion-forming state; when the traffic flow variation degree of the road section in a congestion-forming state is lower than the threshold, it means that the traffic state of the road section has changed to a congested state; when the traffic flow variation degree of the road section in a congested state is greater than the threshold, it means that the traffic state of the road section has changed to a congestion-relief state; and when the traffic flow variation degree of the road section in a congestion-relief is lower than the threshold, it means that the traffic state of the road section has changed to a smooth state; such that the traffic state identified and the traffic state is pre-determined.

The present embodiment further provides a computer storage medium having stored thereon computer program which, when being executed by a processor, implement the above method. The computer storage medium can be considered tangible and non-transitory. Non-limiting examples of the non-transitory tangible computer-readable medium include non-volatile memory circuits (such as flash memory circuits, erasable programmable read-only memory circuits, or masked read-only memory circuits), volatile memory circuits (such as static random access memory circuits or dynamic random access memory circuits), magnetic storage media (such as analog or digital magnetic tapes or hard disk drives), and optical storage media (such as CDs, DVDs, or Blu-ray discs), and the like. The computer program includes processor-executable instructions stored on at least one non-transitory tangible computer-readable medium. The computer program may further include or rely on stored data. The computer program may include a basic input/output system (BIOS) that interacts with the hardware of a special-purpose computer, device drivers that interacts with specific devices of the special-purpose computer, one or more operating systems, user applications, background services, background applications, and the like.

Those skilled in the art should understand that the examples of the present application may be provided as methods, systems, or computer program products, and therefore, the present application may employ full hardware examples, full software examples, or software and hardware combined examples. Moreover, the present application may take the form of a computer program product implemented on one or more computer usable storage media (including, but not limited to, disk memories, CD-ROM, optical memories, and the like) containing computer usable program codes.

The present invention is described with reference to flowcharts and/or block diagrams of methods, devices (systems), and computer program products according to the examples hereof. It should be understood that each flow and/or block in the flow diagrams and/or block diagrams and combinations of the flows and/or blocks in the flowcharts and/or block diagrams may be implemented by computer program instructions. These computer program instructions may be provided for a processor of a general-purpose computer, a special-purpose computer, an embedded processor, or other programmable data processing devices to produce a machine, such that instructions executed by the processor of the computer or other programmable data processing devices produce an apparatus used for implementing functions specified in one or more flows of the flowcharts and/or one or more blocks of the block diagrams.

These computer program instructions may also be stored in a computer readable memory that may guide a computer or other programmable data processing devices to work in a specific manner, such that the instructions stored in the computer readable memory produce an article of manufacture including an instruction device, and the instruction device implements functions specified in one or more flows of the flowcharts and/or one or more blocks of the block diagrams.

These computer program instructions may be loaded onto a computer or another programmable data processing device, such that a series of operations and steps are performed on the computer or other programmable device, thereby generating computer-implemented processing. Therefore, the instructions executed on the computer or other programmable device provide steps for implementing a specific function in one or more flows of the flowcharts and/or in one or more blocks of the block diagrams.

In the present embodiment, a comparative test is conducted between the above solution and the traditional solution. Taking an administrative district of a coastal city subjected to heavy congestion as an example, the present embodiment makes a prediction through the urban-region road network vehicle-passage flow prediction system based on a ConvLSTM and BiLSTM hybrid deep learning model in a scenario of synchronous prediction of complex road networks in the urban areas, and obtains the evaluation indicators as follows: the absolute average error of 26.3, the root mean square error of 34.7, the average absolute error percentage of 0.1, and the prediction accuracy up to 90%. However, when traditional statistical methods and traditional machine learning methods are used to predict the vehicle-passage flow prediction model of the urban-region road network, it is unable to give effective consideration to the temporal and spatial correlation among traffic flow monitoring points, in which case, the evaluation indicators are as follows: the absolute average error of 47.4, the root mean square error of 65.5, the average absolute error percentage of 0.18, and the prediction accuracy of 82% only. The comparison of various indicators and prediction accuracy fully demonstrates the effect of the present invention. By considering the temporal and spatial correlation feature of different checkpoints and synchronous prediction of multiple checkpoints, the present invention realizes real-time and efficient prediction of traffic flow of the urban-region road network.

1. An urban-region road network vehicle-passage flow prediction method based on a hybrid deep learning model, comprising the following steps:
S1: making statistics on traffic flow on the basis of vehicle-passage data of a checkpoint, and calculating real-time vehicle-passage flow and cumulative vehicle-passage flow;
S2: performing spatial and temporal distribution feature analysis on vehicle-passage flow data of the checkpoint based on the flow data obtained in the step S1, and performing feature extraction according to an analysis result to acquire a spatial and temporal influence factor;
S3: constructing and training a ConvLSTM and BILSTM hybrid deep learning model according to the spatial and temporal influence factor;
S4: performing synchronous prediction on traffic flow of an urban-region road network through the constructed ConvLSTM and BILSTM hybrid deep learning model, selecting prediction loss functions and evaluation indicators, and performing visual representation on a result; and
S5: calculating a traffic flow variation degree by means of a linear time series prediction model Prophet, performing traffic state identification, and realizing traffic state pre-determination according to the predication results obtained in the step S4.

2. The urban-region road network vehicle-passage flow prediction method based on a hybrid deep learning model according to claim 1, wherein the step S1 specifically comprises: making statistics of vehicle-passage flow data of a checkpoint of each intersection during each period of time on different time scales, and calculating real-time vehicle-passage flow and cumulative vehicle-passage flow by using the traffic flow statistics module.

3. The urban-region road network vehicle-passage flow prediction method based on a hybrid deep learning model according to claim 1, wherein the step S1 specifically comprises:
A1: making statistics of vehicle-passage flow data of each checkpoint of each intersection during each period of time on different time scales; and
A2: taking the daily set time as the starting time for statistics, and calculating the daily cumulative traffic flow at each intersection.

4. The urban-region road network vehicle-passage flow prediction method based on a hybrid deep learning model according to claim 1, wherein the spatial and temporal distribution feature analysis in the step S2 comprises the temporal distribution periodic feature analysis, temporal distribution trend feature analysis, temporal distribution continuous feature analysis and spatial distribution correlation feature analysis.

5. The urban-region road network vehicle-passage flow prediction method based on a hybrid deep learning model according to claim 4, wherein in the spatial and temporal distribution feature analysis in the step S2, the power spectral method is adopted to analyze the temporal distribution periodic feature of vehicle-passage flow data of the checkpoint; the DBEST model is adopted to analyze the temporal distribution trend feature of vehicle-passage flow data of the checkpoint; a time headway is calculated to analyze the temporal distribution continuous feature of vehicle-passage flow data of the checkpoint; and the correlation matrix method is adopted to analyze the spatial distribution correlation feature of vehicle-passage flow data of the checkpoint.

6. The urban-region road network vehicle-passage flow prediction method based on a hybrid deep learning model according to claim 1, wherein the method for “constructing and training a ConvLSTM and BILSTM hybrid deep learning model” in the step S3 comprises the following steps:
B1: organizing model data, mapping the traffic flow data of a prediction point and traffic flow data points in the vicinity of the prediction point to a one-dimensional data vector, and forming a two-dimensional matrix of one-dimensional vectors at various moments to represent traffic flow data of the predicted checkpoint and its upstream checkpoint during a short period of time;
B2: using the ConvLSTM structure to extract spatial and temporal feature of real-time traffic flow data; using the BiLSTM to extract periodic feature of traffic flow, splicing the two parts of extracted feature data together through a feature fusion layer, and finally performing feature regression through a fully connected network to complete the model construction; and
B3: inputting the real-time checkpoint traffic flow data, checkpoint spatial correlation matrix, and checkpoint historical period traffic flow data into the model for training, and calculating a training result model.

7. The urban-region road network vehicle-passage flow prediction method based on a hybrid deep learning model according to claim 1, wherein the prediction loss functions in the step S4 of the present embodiment are specifically:
$$MAE = \frac{1}{n} {\sum }_{t = 1}^{n} \vert {F}_{p} - {F}_{t} \vert \\ RMSE = \sqrt[2]{\frac{1}{n} {\sum }_{t = 1}^{n} {( {F}_{p} - {F}_{t} )}^{2}} \\ MAPE = \frac{100}{n} {\sum }_{t = 1}^{n} \vert \frac{{F}_{p} - {F}_{t}}{{F}_{t}} \vert \\ Loss = \frac{1}{n} ( {\sum }_{t = 1}^{n} {( {F}_{p} - {F}_{t} )}^{2} + φ {\sum }_{i = 1 n}^{} \vert {W}_{i} \vert + φ {\sum }_{i = 1}^{n} \sqrt{{W}_{i}^{2}} )$$
wherein Fₚ is a deep neural network predicted value of the vehicle-passage flow, Fₜ is an actual value of the vehicle-passage flow, and φ and Wᵢ are parameters of the model; and
Evaluation indicators comprise absolute mean error, root mean square error and mean absolute error percentage.

8. The urban-region road network vehicle-passage flow prediction method based on a hybrid deep learning model according to claim 1, wherein the step S5 specifically comprises:
C1: calculating a traffic flow variation degree, with the calculation formula as follows:
$$P ( f \vert μ , {σ}^{2} ) = \frac{1}{σ \sqrt{2 π}} exp ( - \frac{{( x - μ )}^{2}}{2 {σ}^{2}} ) \\ {v}_{j} = s \cdot {v}_{j - 1} + ( 1 - s ) {( {f}_{j} - {\hat{f}}_{i , j} )}^{2}$$
wherein the expected value u and the variance σ² are two important parameters of normal distribution, the target value f is the truth value of the current traffic flow, vⱼ represents the variance at the j moment, s is the weight value of the preset variance from the previous moment that is continuously retained until the current moment, and fⱼ represents the real traffic flow at the j moment; and
C2: setting a threshold for the traffic flow variation degree: When the traffic flow variation degree of a road section in a smooth state is greater than the threshold, it means that the traffic state of the road section has changed to a congestion-forming state; when the traffic flow variation degree of the road section in a congestion-forming state is lower than the threshold, it means that the traffic state of the road section has changed to a congested state; when the traffic flow variation degree of the road section in a congested state is greater than the threshold, it means that the traffic state of the road section has changed to a congestion-relief state; and when the traffic flow variation degree of the road section in a congestion-relief is lower than the threshold, it means that the traffic state of the road section has changed to a smooth state; such that the traffic state identified and the traffic state pre-determined is realized.

9. An urban-region road network vehicle-passage flow prediction system based on a hybrid deep learning model, comprising a traffic flow statistics module, a checkpoint vehicle-passage flow data spatial-temporal distribution feature analysis module, a training module of an urban-region road network vehicle-passage flow prediction model, a prediction module of an urban-region road network vehicle-passage flow prediction model, and an urban-region road network traffic state pre-determination module; wherein the traffic flow statistics module is used for making statistics of vehicle-passage flow data of a checkpoint of each intersection during each period of time and calculating real-time vehicle-passage flow and cumulative vehicle-passage flow; the checkpoint vehicle-passage flow data spatial-temporal distribution feature analysis module is used for making visual analysis of temporal distribution periodic feature, trend feature, continuous feature and spatial distribution correlation feature of vehicle-passage flow data at the checkpoint; the training module of an urban-region road network vehicle-passage flow prediction model is used for constructing a ConvLSTM and BiLSTM hybrid deep learning model and training input data to form a stable and highly-fitting urban-region road network vehicle-passage flow prediction model; the prediction module of an urban-region road network vehicle-passage flow prediction model is used for inputting historical data related to the urban-region road network vehicle-passage flow that needs to be predicted, and bringing them into the model for prediction; and the urban-region road network traffic state pre-determination module is used for calculating a traffic flow variation degree, and identifying traffic state, so as to realize traffic state pre-determination.
